(19) United States
(12) Patent Application Publication
(10) Pub. No.: US 2021/0402820 A1
(43) Pub. Date: Dec. 30, 2021

(54) IMAGE FORMING METHOD AND IMAGE-FORMED PRODUCT

(71) Applicant: Konica Minolta, Inc., Tokyo (JP)

(72) Inventors: Takuya OKADA, Aichi (JP); Masaki NAKAMURA, Tokyo (JP); Ken NITO, Tokyo (JP)

(21) Appl. No.: 17/340,693

(22) Filed: Jun. 7, 2021

(30) Foreign Application Priority Data
Jun. 24, 2020 (JP) 2020-108849

(51) Int. Cl. B41M 5/50; B41J 2/21; B41J 11/00; C23C 16/40; B05D 1/00; C23C 16/30; C23C 14/10; C23C 14/34; C23C 16/50

(52) U.S. Cl. CPC B41M 5/502; B41J 2/21; B41J 11/0015; C23C 16/402; B05D 1/60; C23C 16/50; C23C 16/403; C23C 16/401; C23C 14/10; C23C 14/34; C23C 16/30

(57) ABSTRACT

A image forming method of the present invention includes steps of forming a coloring material layer by applying an ink containing water and a dispersible coloring material dispersed in the water to the surface of a fabric by an inkjet method; and forming, on a surface of the coloring material layer, a protective layer having an average thickness smaller than that of the coloring material layer.

### CROSS REFERENCE TO RELATED APPLICATIONS

The entire disclosure of Japanese Patent Application No. 2020-108849, filed on Jun. 24, 2020 is incorporated herein by reference in its entirety.

### BACKGROUND

### Technological Field

An image forming method and an image-formed product (product on which an image is formed).

### Description of Related Art

The present invention relates to an image forming method and an image-formed product.

As a textile printing method, printing for forming an image on a fabric by an inkjet method, which is often referred to as inkjet textile printing, has been widely used because the time required for a dyeing process is short, the production efficiency is high, and the like.

The inkjet textile printing forms an image by ejecting minute droplets of an ink from an inkjet recording head to be landed on a fabric. The types of coloring materials contained in inks to be used in the inkjet textile printing include dyes and pigments.

In inkjet textile printing using a dye-based ink, the dye contained in the ink dissolves in the fibers of a fabric or reacts with the fibers, so that an image having high fixability can be readily obtained without impairing the texture of the fibers; however, a step is required to wash away the undissolved dye or the unreacted dye.

From the viewpoint of, for example, omitting such a washing step, inkjet textile printing using a pigment-based ink is studied. For example, known is an inkjet textile printing method in which a pigment-based ink is ejected by an inkjet method to be adhered to a fabric, and then a coating composition is further adhered thereto (Japanese Patent Application Laid-Open No. 2019-99790). The friction fastness is said to be improved by increasing the Young's modulus of the coating film of the coating composition to be higher than the Young's modulus of the coating film of the pigment-based ink.

Compared with a coating film obtained by using a dye-based ink, a coating film obtained by using a pigment-based ink is more likely to form unevenness on the surface of the coating film due to the particles of a dispersible coloring material such as a pigment. A pigment-based ink is thus more likely to cause irregular reflection of light to lower the color density.

A similar problem may occur in an image-formed product including a coating film (coloring material layer) of a pigment-based ink and a coating film (protective layer) of a coating composition described in Japanese Patent Application Laid-Open No. 2019-99790.

The present invention has been made in the view of the above situations, and an object of the present invention is to provide an image forming method capable of preventing a decrease in color density in an image-formed product obtained by using an ink containing a dispersible coloring material, and to provide the image-formed product.

### SUMMARY

The present invention relates to an image forming method and an image-formed product as follows.

To achieve at least one of the abovementioned objects, according to an aspect of the present invention, an image forming method reflecting one aspect of the present invention includes forming a coloring material layer by applying an ink containing water and a dispersible coloring material dispersed in the water to the surface of a fabric by an inkjet method; and forming a protective layer having an average thickness smaller than that of the coloring material layer, on the surface of the coloring material layer.

To achieve at least one of the abovementioned objects, according to another aspect of the present invention, an image-formed product reflecting one aspect of the present invention includes a fabric, a coloring material layer, and a protective layer in this order, and the coloring material layer contains a dispersible coloring material, and the average thickness of the protective layer is smaller than the average thickness of the coloring material layer.

### DETAILED DESCRIPTION OF EMBODIMENTS

Hereinafter, one or more embodiments of the present invention will be described with reference to the drawings. However, the scope of the invention is not limited to the disclosed embodiments.

Japanese Patent Application Laid-Open No. 2019-99790 shows no relation between the thickness of a coloring material layer and the thickness of a protective layer; however, the thickness of a protective layer is generally larger than the thickness of a coloring material layer. As with an image-formed product without a protective layer, the color density is more likely to decrease due to irregular reflection of light on the surface of an image-formed product obtained in such a way.

In particular, in a coloring material layer containing a dispersible coloring material such as a pigment and a polymeric dispersant or a binder resin, reducing the content ratio of the polymeric dispersant or the binder resin to increase the content ratio of the dispersible coloring material is more likely to increase the unevenness on the surface of the coloring material layer. The color density is thus likely to further decrease due to irregular reflection of light.

The present inventors have newly found out that the color density of a coloring material layer can be increased by setting the thickness of a protective layer to be smaller than the thickness of the coloring material layer.

This mechanism is not clear, but it is presumed as follows. A protective layer having a thickness larger than that of a coloring material layer is more likely to increase the unevenness on the surface of the protective layer (according to the thickness), and the unevenness superposing over the unevenness on the surface of the coloring material layer are more likely to further increase the unevenness on the surface of the protective layer. The unevenness on the surface of the protective layer thus tends to reflect light irregularly, the color of the coloring material layer becomes whitish, and the color density tends to decrease. Setting the thickness of the protective layer to be smaller than the thickness of the coloring material layer can reduce the unevenness on the surface of the protective layer, thereby preventing the decrease in color density. Hereinafter, the configuration of the present invention will be described.

1. Image Forming Method

The image forming method of the present invention includes steps of 1) forming a coloring material layer on the surface of a fabric by applying an ink (inkjet textile printing ink) containing a dispersible coloring material and water to the surface by an inkjet method; and 2) forming a protective layer on the surface of the coloring material layer.

Step 1) (Step of Forming Coloring Material Layer)

A fabric is prepared.

The fiber material constituting the fabric may be any fiber, and may be a natural fiber such as cotton (cellulose fiber), linen, wool, or silk, or a chemical fiber such as rayon, vinylon, nylon, acryl, polyurethane, polyester, or acetate. The fabric may be in any form of these fibers, such as a woven fabric, a non-woven fabric, or a knitted fabric. The fabric may be a blended woven fabric or blended non-woven fabric of two or more types of fibers. The fabric may be pretreated (see the below described Step 3)).

An ink is then applied by an inkjet method to the surface of the fabric. Specifically, the ink is ejected from an inkjet recording head to apply droplets of the ink.

As will be described below, the ink is a water-based ink containing a dispersible coloring material, such as a pigment, and water. From the viewpoint of enhancing the dispersibility of the dispersible coloring material, the ink preferably further contains a polymeric dispersant or contains a self-dispersing pigment as the dispersible coloring material. The details of the configuration of the ink will be described below.

The ink applied to the fabric is then dried and fixed to form a coloring material layer.

The drying and fixing are preferably performed by heating. That is, the drying method may be any method, such as a method using a heater, a hot air dryer, or a heat roller. In particular, it is preferable to heat both sides of the fabric to dry the fabric by using a hot air dryer and a heater.

The drying temperature may be any value, but is preferably 110° C. or higher, more preferably 130 to 180° C., from the viewpoint of sufficiently removing solvent components such as water contained in the applied ink. The drying time, which depends on the drying temperature, may be, for example, about 0.5 to 10 minutes.

The obtained coloring material layer contains a dispersible coloring material and a polymeric dispersant and/or a binder resin. The composition of the coloring material layer is the same as the composition of the solid content of the ink described below.

The average thickness t1 of the coloring material layer may be any value which does not impair the texture of the fabric, but is preferably, for example, 0.3 to 1.5 μm. A coloring material layer whose average thickness t1 is 0.3 μm or more is more likely to achieve a sufficient color density, and a coloring material layer whose average thickness t1 is 1.5 μm or less is more likely to prevent worsening of texture due to stiffness. From the same viewpoint, the average thickness t1 of the coloring material layer is more preferably 0.6 to 1 μm.

The average thickness t1 of the coloring material layer can be measured by cutting the coloring material layer together with the fabric in the cross-sectional direction for observation by an electron microscope.

Specifically, as the thickness of the coloring material layer varies depending on the measurement location, three samples in the main scanning direction at both ends and the center (for example, positions at 3 equally divided parts), and three samples in the sub scanning direction at equal intervals (for example, at 5 cm intervals), nine samples in total, are taken in an image-formed product.

Each sample is then cut in a direction parallel to the main scanning direction, and the thickness of the coloring material layer adhering to the fabric on the cut surface is measured in an electron microscope image of the sample, for example, at 10 points (90 points in total). The average value of the measured thickness is defined as “the average thickness t1 of the coloring material layer.” The main scanning direction is typically the width direction of an image-formed product (or a fabric). For cutting the sample in the cross-sectional direction, the sample may be cut in a state of being cooled with liquid nitrogen from the viewpoint of preventing the deformation of the cut surface by cutting, which allows for more accurate measurement.

Step 2) (Step of Forming Protective Layer)

A protective layer is then formed on the obtained coloring material layer.

The protective layer is preferably transparent from the viewpoint of making the coloring material layer visible (through the protective layer). Specifically, the transmittance of the protective layer for light having a wavelength of 400 to 700 nm is preferably 80% or more. The transmittance can be obtained by measuring the transmittance of a protective layer having a known thickness by a spectrophotometer and converting the measured transmittance into transmittance of the target protective layer at the actual thickness.

The average thickness t2 of the protective layer is smaller than the average thickness t1 of the coloring material layer. As a result, the unevenness on the surface of the protective layer due to the unevenness on the surface of the coloring material layer can be reduced, and then the decrease in color density due to irregular reflection of light can be prevented.

Specifically, the ratio t2/t1 of the average thickness t1 of the coloring material layer and the average thickness t2 of the protective layer is preferably 0.95 or less. When t2/t1 is 0.95 or less, the unevenness on the surface of the protective layer can be reduced, so that the decrease in color density due to irregular reflection of light may be further prevented. The lower limit of t2/t1 may be any value, but is preferably 0.1 or more from the viewpoint of facilitating prevention of increase in the unevenness on the surface of the protective layer caused by cracking in the protective layer from rubbing. From the same viewpoint, t2/t1 is more preferably 0.7 to 0.9. The average thickness t2 of the protective layer can be measured by the same method as described above.

Such a protective layer is preferably a thin film formed by a thin film forming process (gas phase method). The thin film may be an inorganic thin film or a resin thin film.

An inorganic material constituting the inorganic thin film and a resin material constituting the resin thin film preferably have a refractive index higher than the refractive index of air (1.0) and lower than the refractive index of the dispersible coloring material contained in the coloring material layer. As a result, in addition to the effect of reducing the unevenness on the surface of the image-formed product, the difference in refractive index between the layers (the difference in refractive index between the air layer and the protective layer and between the protective layer and the coloring material layer) can be reduced. Irregular reflection of light on the surface of the image-formed product thus can be further reduced and the color density can be further increased.

Specifically, the refractive index of the inorganic material and the resin material for light having a wavelength of 589.3 nm is preferably 1.2 to 1.9, and more preferably 1.3 to 1.7. A protective layer whose refractive index is within the above range can reduce the difference in the refractive index between the air layer and the protective layer and the difference in the refractive index between the protective layer and the coloring material layer, thereby further reducing irregular reflection of light on the surface of the image-formed product and further increasing the color density.

In addition, when the refractive index of the dispersible coloring material contained in the coloring material layer for light having a wavelength of 589.3 nm is defined as n1, and the refractive index of the inorganic material or resin material contained in the protective layer for light having a wavelength of 589.3 nm is defined as 112, the difference between n1 and n2 (n1-n2) is preferably 0.7 or less.

The refractive indices of the inorganic material and the resin material contained in the protective layers and the dispersible coloring material contained in the coloring material layer can be measured according to JIS K0062: 1992.

The inorganic material may be any material which has a refractive index as described above, and examples of such a inorganic material include metal oxides such as silicon dioxide (silica), silicon monoxide, aluminum oxide, and magnesium oxide, and metal fluorides such as magnesium fluoride and calcium fluoride. The resin material may be any material which has a refractive index as described above, and examples of such a resin material include fluororesins such as PTFE, acrylic resins such as PMMA, olefin resins such as polyethylene, and urethane resins.

The content of the inorganic material or the resin material is preferably 80% by mass or more, and more preferably 90 to 100% by mass with respect to the protective layer.

The protective layer may additionally contain components other than the above described components as long as the effects of the present invention are not impaired.

The refractive indices of the protective layer and the coloring material layer can be adjusted by their compositions. For example, when the protective layer is a thin film composed of an inorganic material or a resin material, the refractive index of the protective layer is the same as the refractive index of the individual inorganic material or the resin material.

The method for forming the protective layer is preferably a thin film forming process (gas phase method), as described above. Examples of the thin film forming method (process) include PVD methods (physical vapor deposition methods) such as a vacuum vapor deposition method and a sputtering method; and CVD methods (chemical vapor deposition methods) such as a plasma CVD method.

From the viewpoint of productivity, for example, the vacuum vapor deposition method is preferred. The heating means for a vacuum vapor deposition apparatus used in the vacuum vapor deposition method may be any one of an electron beam heating method, a resistance heating method, and an induction heating method. In addition, from the viewpoint of increasing the transparency of the protective layer, reaction vapor deposition may be performed by blowing oxygen gas or the like during the vapor deposition.

The image forming method of the present invention may further include a step 3) of pretreating a fabric, if necessary.

Step 3) (Step of Pretreatment)

The pretreatment can be performed by applying a pretreatment agent to the fabric.

The pretreatment agent may be any agent which contains a component that increases the fixability of the ink on the surface of a fabric. Examples of such components include compounds having an anionic group (for example, carboxyl group, phosphate group, phosphonic acid group, and sulfonic acid group), and compounds having a cationic group (for example, amino group and quaternary ammonium group).

Examples of the compounds having a cationic group include polyvalent metal salts, resins having a cationic group (for example, cationic urethane resins and cationic olefin resins), and cationic surfactants.

Examples of the compounds having an anionic group include resins having an anionic group (for example, outer part of plant such as pectinic acid, fibrous derivatives such as carboxymethyl cellulose, processed starches such as carboxymethyl starch and carboxyethyl starch, and acrylic polymers containing acrylic acid as a copolymerization component, such as acrylic acid/acrylic acid ester copolymers, styrene/acrylic acid copolymer), and anionic surfactants.

The pretreatment agent may further contain a pH adjuster, a preservative, and/or the like, if necessary. As the preservative, the same preservatives as those mentioned as the preservatives for ink can be used.

Any method for applying the pretreatment agent to a fabric, such as a pad method, a coating method, a spray method, and an inkjet method, may be used.

The pretreatment agent applied to the fabric may be heated and dried by using hot air, a hot plate, or a heat roller.

In the following, the configuration of an ink to be used in the image forming method of the present invention will be described.

2. Ink

The ink contains a dispersible coloring material and water.

2-1. Dispersible Coloring Material

The dispersible coloring material may be any material, and may be a solid dye such as a disperse dye or a pigment. In particular, pigments are preferred from the viewpoint of readily forming an image having excellent weather resistance.

(Pigment)

The pigment may be any one of, for example, organic pigments and inorganic pigments having the following numbers listed in the Color Index.

Examples of red or magenta pigments include Pigment Red 3, 5, 19, 22, 31, 38, 43, 48:1, 48:2, 48:3, 48:4, 48:5, 49:1, 53:1, 57:1, 57:2, 58:4, 63:1, 81, 81:1, 81:2, 81:3, 81:4, 88, 104, 108, 112, 122, 123, 144, 146, 149, 166, 168, 169, 170, 177, 178, 179, 184, 185, 208, 216, 226, and 257, Pigment Violet 3, 19, 23, 29, 30, 37, 50, and 88, and Pigment Orange 13, 16, 20, and 36.

Examples of blue or cyan pigments include Pigment Blue 1, 15, 15:1, 15:2, 15:3, 15:4, 15:6, 16, 17-1, 22, 27, 28, 29, 36, and 60.

Examples of green pigments include Pigment Green 7, 26, 36, and 50. Examples of yellow pigments include Pigment Yellow 1, 3, 12, 13, 14, 17, 34, 35, 37, 55, 74, 81, 83, 93, 94, 95, 97, 108, 109, 110, 137, 138, 139, 153, 154, 155, 157, 166, 167, 168, 180, 185, and 193.

Examples of black pigments include Pigment Black 7, 26, and 28.

Examples of commercially available products of such pigments include Chromofine Yellow 2080, 5900, 5930, AF-1300, and 2700L, Chromofine Orange 3700L and 6730, Chromofine Scarlet 6750, Chromofine Magenta 6880, 6886, 6891N, 6790, and 6887, Chromofine Violet RE, Chromofine Red 6820 and 6830, Chromofine Blue HS-3, 5187, 5108, 5197, 5085N, SR-5020, 5026, 5050, 4920, 4927, 4937, 4824, 4933GN-EP, 4940, 4973, 5205, 5208, 5214, 5221, and 5000P, Chromofine Green 2GN, 2GO, 2G-550D, 5310, 5370, and 6830, Chromofine Black A-1103, Seikafast Yellow 10GH, A-3, 2035, 2054, 2200, 2270, 2300, 2400(B), 2500, 2600, ZAY-260, 2700(B), and 2770, Seikafast Red 8040, C405(F), CA120, LR-116, 1531B, 8060R, 1547, ZAW-262, 1537B, GY, 4R-4016, 3820, 3891, and ZA-215, Seikafast Carmine 6B1476T-7, 1483LT, 3840, and 3870, Seikafast Bordeaux 10B-430, Seikalight Rose R40, Seikalight Violet B800, 7805, Seikafast Maroon 460N, Seikafast Orange 900 and 2900, Seikalight Blue C718, A612, and Cyanine Blue 4933M, 4933GN-EP, 4940, and 4973 (from Dainichiseika Color & Chemicals Mfg. Co., Ltd.);

KET Yellow 401, 402, 403, 404, 405, 406, 416, and 424, KET Orange 501, KET Red 301, 302, 303, 304, 305, 306, 307, 308, 309, 310, 336, 337, 338, and 346, KET Blue 101, 102, 103, 104, 105, 106, 111, 118, and 124, and KET Green 201 (from DIC Corporation);

Colortex Yellow 301, 314, 315, 316, P-624, 314, U10GN, U3GN, UNN, UA-414, and U263, Finecol Yellow T-13 and T-05, Pigment Yellow 1705, Colortex Orange 202, Colortex Red 101, 103, 115, 116, D3B, P-625, 102, H-1024, 105C, UFN, UCN, UBN, U3BN, URN, UGN, UG276, U456, U457, 105C, and USN, Colortex Maroon 601, Colortex Brown B610N, Colortex Violet 600, Pigment Red 122, Colortex Blue 516, 517, 518, 519, A818, P-908, and 510, Colortex Green 402 and 403, and Colortex Black 702 and U905 (from Sanyo Color Works, LTD.);

Lionol Yellow 1405G, Lionol Blue FG7330, FG7350, FG7400G, FG7405G, ES, and ESP-S (from Toyo Ink Co., Ltd.), and Toner Magenta E02, Permanent Rubin F6B, Toner Yellow HG, Permanent Yellow GG-02, and Hostapeam Blue B2G (from Hoechst Industry Limited.);

Novoperm P-HG, Hostaperm Pink E, and Hostaperm Blue B2G (from Clariant); and

Carbon Black #2600, #2400, #2350, #2200, #1000, #990, #980, #970, #960, #950, #850, MCF88, #750, #650, MA600, MA7, MA8, MA11, MA100, MA100R, MA77, #52, #50, #47, #45, #45L, #40, #33, #32, #30, #25, #20, #10, #5, #44, and CF9 (from Mitsubishi Chemical Corporation).

(Self-Dispersing Pigment)

The pigment may be a self-dispersing pigment. The self-dispersing pigment is obtained by modifying the surface of pigment particles with groups having hydrophilic groups so that the self-dispersing pigment has pigment particles and groups having hydrophilicity bonded to the surface thereof.

Examples of the hydrophilic groups include carboxyl groups, sulfonic acid groups, and phosphorus-containing groups. Examples of the phosphorus-containing groups include phosphate groups, phosphonic acid groups, phosphinic acid groups, phosphite groups, and phosphate groups.

Examples of commercially available products of such self-dispersing pigments include Cab-O-Jet™ 200 K, 250C, 260M, 270V (sulfonic acid group-containing self-dispersing pigment), Cab-O-Jet™ 300 K (carboxylic acid group-containing self-dispersing pigment), Cab-O-Jet™ 400 K, 450C, 465M, 470V, 480V (phosphate group-containing self-dispersing pigment) from Cabot Corporation.

The content of the dispersible coloring material may be any value, preferably 1.5 to 15 mass % with respect to the ink from the viewpoint that the viscosity of the ink can be readily adjusted within the above range and a high-density image can be formed. A dispersible coloring material whose content is 1.5 mass % or more is more likely to form a high-density image, and a dispersible coloring material whose content is 15 mass % or less prevents the viscosity of the ink from becoming too high, and thus is less likely to impair the injection stability. From the same viewpoint, the content of the dispersible coloring material is more preferably 5 to 15 mass % with respect to the ink.

2-2. Additional Components

The ink may additionally contain other components, if necessary. Examples of the additional components may include solvents other than water, polymeric dispersants, binder resins, preservatives, and pH adjusters.

(Solvent)

Any solvent may be used, but the solvent is preferably a water-soluble organic solvent. Any water-soluble organic solvent which is compatible with water may be used, but from the viewpoints of facilitating the permeation of the ink into a fabric and allowing the injection stability to be less likely to be impaired in an inkjet method, it is preferable that the ink is less likely to thicken due to drying. The ink thus preferably contains a high boiling point solvent having a boiling point of 200° C. or higher.

The high boiling point solvent having a boiling point of 200° C. or higher may be any water-soluble organic solvent having a boiling point of 200° C. or higher, and is preferably any one of polyols or polyalkylene oxides.

Examples of the polyols having a boiling point of 200° C. or higher include dihydric alcohols such as 1,3-butanediol (boiling point 208° C.), 1,6-hexanediol (boiling point 223° C.), and polypropylene glycol; and trihydric or higher alcohols such as glycerin (boiling point 290° C.), trimethylolpropane (boiling point 295° C.).

Examples of the polyalkylene oxides having a boiling point of 200° C. or higher include diethylene glycol monoethyl ether (boiling point 202° C.), triethylene glycol monomethyl ether (boiling point 245° C.), tetraethylene glycol monomethyl ether (boiling point 305° C.), tripropylene glycol monoethyl ether (boiling point 256° C.); and ethers of divalent alcohols such as polypropylene glycol and ethers of trihydric or higher alcohols such as glycerin (boiling point 290° C.) and hexanetriol.

The solvent may further contain a solvent other than the above-described high boiling point solvent. As another solvent, any solvent the same as the specific example of the solvent contained in the pretreatment agent can be used.

(Polymeric Dispersant)

When the pigment is not a self-dispersing pigment, the ink preferably further contains a polymeric dispersant from the viewpoint of facilitating the dispersion of the pigment.

The polymeric dispersant may be of any type, and may be any one of cationic dispersants, anionic dispersants, and nonionic dispersants.

Examples of cationic groups contained in the cationic dispersants may include secondary amino groups (imino group), tertiary amino groups, and quaternary ammonium groups.

Such a cationic dispersant may be any dispersant capable of forming a pigment dispersion, and examples of the dispersant include acrylic (co)polymers having a cationic group (tertiary amino group or quaternary ammonium group).

The anionic dispersant is a polymeric dispersant having a hydrophilic group selected from the group consisting of a carboxylic acid group, a phosphorus-containing group, and a sulfonic acid group.

Examples of the polymeric dispersants having a carboxylic acid group include polycarboxylic acids and salts thereof. Examples of polycarboxylic acids include (co)polymers of a monomer selected from acrylic acid or derivatives thereof, maleic acid or derivatives thereof, itaconic acid or derivatives thereof, and fumaric acid or derivatives thereof, and salts of the (co)polymers.

The polymeric dispersant having a phosphorus-containing group is a polymeric dispersant having a phosphate group or a phosphoric acid group. Examples of the polymeric dispersant having a phosphate group or a phosphoric acid group include alkyl phosphate esters or salts thereof.

Examples of the polymeric dispersant having a sulfonic acid group include formalin condensates of aromatic sulfonic acids and formalin condensates of lignin sulfonic acids, and a formalin condensate of an aromatic sulfonic acid is preferred. Examples of the formalin condensates of aromatic sulfonic acids include condensed sodium naphthalene sulfonate.

Examples of the nonionic dispersant include polyoxyalkylenes and polyoxyalkylene alkyl ethers.

The content of the polymeric dispersant is preferably 10 to 50 mass % with respect to the dispersible coloring material. A polymeric dispersant whose content is 10 mass % or more is more likely to sufficiently increase the dispersibility of the dispersible coloring material, and a polymeric dispersant whose content is 50 mass % or less is more likely to prevent an excessive increase in viscosity. From the same viewpoint, the content of the polymeric dispersant is preferably 20 to 40 mass % with respect to the dispersible coloring material.

(Binder Resin)

The binder resin may be a water-soluble resin or resin particles (water-dispersible resin).

The weight average molecular weight of the binder resin may be 10,000 or more. The weight average molecular weight can be measured in terms of polystyrene by the GPC method.

From the viewpoint of allowing the texture of a fabric to be less likely to be impaired, the content ratio of the polymeric dispersant and the binder resin is preferably small. When the content ratio is small, the content ratio of the dispersible coloring material is increased, so that the unevenness on the surface of the coloring material layer may be increased. The present invention is particularly effective in such a case.

Specifically, the ratio of the total content of the polymeric dispersant and the binder resin with respect to the content of the dispersible coloring material is preferably 1.5 or less, more preferably 1.2 or less, in terms of mass ratio.

(Preservative and pH Adjuster)

As the preservative and pH adjuster, any preservative and pH adjuster the same as the specific examples of the preservative and pH adjuster optionally contained in the pretreatment agent can be used.

2-3. Physical Properties

The viscosity of the ink at 25° C. may be any value such that the ejection property by the inkjet method becomes suitable, but is preferably 3 to 20 mPa·s, and more preferably 4 to 12 mPa·s. The viscosity of the ink can be measured by an E-type viscometer at 25° C.

2-4. Preparation of Ink

The ink can be produced by any method, for example, through a step of mixing the above-described dispersible coloring material, water, and an optional dispersant.

3. Image-Formed Product

An image-formed product obtained by the image forming method of the present invention includes a fabric, a coloring material layer, and a protective layer.

As described above, the average thickness t2 of the protective layer is smaller than the average thickness t1 of the coloring material layer. Specifically, t2/t1 satisfies the above-described range. As a result, the unevenness on the surface of the image-formed product due to the unevenness on the surface of the coloring material layer can be reduced, and the decrease in color density due to irregular reflection of light can be prevented.

The embodiment of the present invention can provide an image forming method capable of preventing a decrease in color density in an image-formed product obtained by using an ink containing a dispersible coloring material; and the image-formed product.

### Examples

Hereinafter, the present invention will be specifically described with reference to Examples, but the present invention is not limited thereto.

1. Material of Ink

(1) Dispersible Coloring Material (Pigment)

Pigment Red 122 (Refractive index for light having a wavelength of 589.3 nm: 2.0)

(2) Polymeric Dispersant

Styrene/acrylic copolymer (anionic dispersant, weight average molecular weight 16,000)

(3) Solvent

Ethylene glycol (boiling point 197.6° C.)

Glycerin (boiling point 290° C.)

Propylene glycol (boiling point 188.2° C.)

<Preparation of Inks 1 to 4>

The components shown in Table 1 were mixed to have the compositions shown in Table 1, thereby obtaining inks 1 to 4.

TABLE 1
Unit: parts by mass

| | | Ink | | | |
|---|---|---|---|---|---|
| | | 1 | 2 | 3 | 4 |
| Pigment | Pigment Red 122 | 4 | 4 | 4 | 4 |
| Polymeric | Styrene/acrylic | 4.8 | 6 | 8 | 12 |
| Dispersant | Copolymer | | | | |
| Dispersant/Pigment (Mass Ratio) | | 1.2 | 1.5 | 2.0 | 3.0 |
| Solvent | Ethylene Glycol | 20 | 20 | 20 | 20 |
| | Glycerin | 10 | 10 | 10 | 10 |
| | Propylene Glycol | 10 | 10 | 10 | 10 |

| | | | | |
|---|---|---|---|---|
| Ion-exchanged Water | 51.2 | 50 | 48 | 44 |

2. Image Formation and Evaluation

<Tests 1 to 20 and 23 to 29>

(1) Pretreatment

The following fabrics 1 to 3 were prepared.

Fabric 1: 100% polyester fabric

Fabric 2: 100% cotton fabric

Fabric 3: Blended fabric of 50% cotton and 50% polyester

The pretreatment was performed by applying a pretreatment agent containing 3 parts by mass of a styrene/acrylic acid copolymer (anionic pretreatment agent) and 97 parts by mass of water to the surface of the fabric by immersion, then squeezing and drying the fabric.

(2) Formation of Coloring Material Layer

As an image forming apparatus, an inkjet printer including an inkjet head (Head KM1024iMAE from Konica Minolta, Inc.) was prepared. Then, an ink shown in Table 2 or 3 was ejected from the nozzle of the above inkjet head to form a solid image on a pretreated fabric in such a way that the average thickness of the obtained coloring material layer was set at a value as shown in Table 2 or 3. Specifically, a solid image (200 mm×200 mm) was formed by a main scan of 540 dpi×a sub scan of 720 dpi. The “dpi” represents the number of ink droplets (dots) per 2.54 cm. The ejection frequency was 22.4 kHz.

The fabric with the solid image formed thereon was dried at 150° C. for 3 minutes in a belt-conveying dryer, thereby obtaining an coloring material layer having an average thickness shown in Table 2 or 3.

(3) Formation of Protective Layer

A fabric with a solid image formed thereon was set in a vacuum vapor deposition apparatus OTFC-1300 (from Optorun Co., Ltd.), and the material shown in Table 2 or 3 was subjected to vacuum vapor deposition to form a protective layer in such a way that the average thickness of the obtained protective layer was set at the value shown in Table 2 or 3. As a result, an image-formed product including a (pretreated) fabric, a coloring material layer, and a protective layer was obtained.

<Test 21>

An image-formed product was obtained in the same manner as in Test 1 except that the protective layer was formed by a sputtering method using sputtering apparatus NSC-15 (from Optomn Co., Ltd.).

<Test 22>

An image-formed product was obtained in the same manner as in Test 1 except that the protective layer was formed by a plasma CVD method using plasma CVD device CME-200E (from ULVAC, Inc.).

<Tests 30 and 31>

The following components were mixed to prepare a composition for a protective layer.

(Composition)

Urethane resin: 5 parts by mass

Ethylene glycol: 30 parts by mass

Ion-exchanged water: 65 parts by mass

An image-formed product was obtained in the same manner as in Test 1 except that the prepared composition was applied onto a coloring material layer by the method shown in Table 3 and then dried at 150° C.

<Test 32>

An image-formed product was obtained in the same manner as in Test 1 except that a protective layer was not formed.

<Measurement of Thickness>

The average thickness t1 of the coloring material layer of each of the image-formed products obtained in Tests 1 to 32 was measured by the following methods.

Specifically, three samples in the main scanning direction at both ends and the center (positions at 3 equally divided parts) and three samples in the sub scanning direction at equal intervals (at 5 cm intervals), nine samples in total, were taken in the obtained image-formed product.

Each sample is then cut in a direction parallel to the main scanning direction, and the thickness of the coloring material layer adhering to the fabric on the cut surface was measured at 10 points (90 points in total) from an electron microscope of the sample. The average value of the measured thickness was defined as “the average thickness t1 of a coloring material layer.” The main scanning direction was the width direction of an image-formed product. The average thickness t2 of a protective layer was also measured by the same method.

<Evaluation>

The image-formed products obtained in Tests 1 to 32 were evaluated for color density of the image and the texture by the following methods.

(Color Density)

The color density of the image-formed product was sensorily evaluated for the density change before and after the provision of the protective layer. Evaluation was made based on the following evaluation criteria.

Excellent: Obvious improvement in density was confirmed after provision of the protective layer

Good: Improvement in density was confirmed

Poor: Improvement in density was not confirmed, or the density was decreased

When the evaluation was “Good” or better, the color density was evaluated to be favorable.

(Texture)

The texture of an obtained image-formed product and a fabric was evaluated sensorily by touching the object with fingers. Evaluation was made based on the following evaluation criteria.

Excellent: Softness of the original fabric was maintained

Good: Softness of the original fabric is lost and the fabric becomes a little harder, but the texture of the fabric was not impaired

Poor: The fabric became harder than the original fabric, and the texture of the fabric was impaired

When the evaluation was “Good” or better, the texture was evaluated as in an allowable range.

Table 2 shows the evaluation results of Tests 1 to 20, and Table 3 shows the evaluation results of Tests 21 to 32.

The refractive index of each material was measured according to JIS K0062: 1992. The transmittance of each protective layer for light having a wavelength of 400 to 700 nm was measured with spectrophotometer V-550 (from JASCO Corporation) and found to be 80% or more.

TABLE 2

| | | Coloring Material Layer | | | | | | |
|---|---|---|---|---|---|---|---|---|
| | | | Dispersant/ | Refractive | | Protective Layer | | |
| | | | Coloring | Index of | Average | | Refractive | |
| | | | Material | Coloring | Thickness | | Index of | |
| | Fabric | Ink | Content Ratio | Material | t1 | | Material | Forming |
| Test | Type | No | (Mass Ratio) | (—) | (μm) | Material | (—) | Method |
| 1 | Fabric 1 | 1 | 1.2 | 2.0 | 0.6 | Silicon | 1.47 | Vacuum Vapor |
| | (Polyester) | | | | | Dioxide | | Deposition |
| 2 | Fabric 1 | 1 | 1.2 | | 0.6 | Silicon | 1.47 | Vacuum Vapor |
| | (Polyester) | | | | | Dioxide | | Deposition |
| 3 | Fabric 1 | 1 | 1.2 | | 0.6 | Silicon | 1.47 | Vacuum Vapor |
| | (Polyester) | | | | | Dioxide | | Deposition |
| 4 | Fabric 2 | 1 | 1.2 | | 0.6 | Silicon | 1.47 | Vacuum Vapor |
| | (Cotton) | | | | | Dioxide | | Deposition |
| 5 | Fabric 2 | 1 | 1.2 | | 0.6 | Silicon | 1.47 | Vacuum Vapor |
| | (Cotton) | | | | | Dioxide | | Deposition |
| 6 | Fabric 2 | 1 | 1.2 | | 0.6 | Silicon | 1.47 | Vacuum Vapor |
| | (Cotton) | | | | | Dioxide | | Deposition |
| 7 | Fabric 3 | 1 | 1.2 | | 0.6 | Silicon | 1.47 | Vacuum Vapor |
| | (Blended) | | | | | Dioxide | | Deposition |
| 8 | Fabric 1 | 1 | 1.2 | | 1.0 | Silicon | 1.47 | Vacuum Vapor |
| | (Polyester) | | | | | Dioxide | | Deposition |
| 9 | Fabric 1 | 1 | 1.2 | | 1.0 | Silicon | 1.47 | Vacuum Vapor |
| | (Polyester) | | | | | Dioxide | | Deposition |
| 10 | Fabric 1 | 1 | 1.2 | | 1.0 | Silicon | 1.47 | Vacuum Vapor |
| | (Polyester) | | | | | Dioxide | | Deposition |
| 11 | Fabric 1 | 1 | 1.2 | | 1.0 | Silicon | 1.47 | Vacuum Vapor |
| | (Polyester) | | | | | Dioxide | | Deposition |
| 12 | Fabric 1 | 1 | 1.2 | | 1.0 | Silicon | 1.47 | Vacuum Vapor |
| | (Polyester) | | | | | Dioxide | | Deposition |
| 13 | Fabric 1 | 1 | 1.2 | | 0.6 | PTFE | 1.35 | Vacuum Vapor |
| | (Polyester) | | | | | | | Deposition |
| 14 | Fabric 1 | 1 | 1.2 | | 0.6 | Magnesium | 1.38 | Vacuum Vapor |
| | (Polyester) | | | | | Fluoride | | Deposition |
| 15 | Fabric 1 | 1 | 1.2 | | 0.6 | Calcium | 1.40 | Vacuum Vapor |
| | (Polyester) | | | | | Fluoride | | Deposition |
| 16 | Fabric 1 | 1 | 1.2 | | 0.6 | PMMA | 1.49 | Vacuum Vapor |
| | (Polyester) | | | | | | | Deposition |
| 17 | Fabnc 1 | 1 | 1.2 | | 0.6 | Polyethylene | 1.53 | Vacuum Vapor |
| | (Polyester) | | | | | | | Deposition |
| 18 | Fabric 1 | 1 | 1.2 | | 0.6 | Aluminum | 1.64 | Vacuum Vapor |
| | (Polyester) | | | | | Oxide | | Deposition |
| 19 | Fabric 1 | 1 | 1.2 | | 0.6 | Magnesium | 1.74 | Vacuum Vapor |
| | (Polyester) | | | | | oxide | | Deposition |
| 20 | Fabric 1 | 1 | 1.2 | | 0.6 | Silicon | 1.90 | Vacuum Vapor |
| | (Polyester) | | | | | Monoxide | | Deposition |

| | Protective Layer | | | | | |
|---|---|---|---|---|---|---|
| | Ayerage | | | | | |
| | Thickness | | Evaluation | | | |
| | t2 | t2/t1 | Color | | | |
| Test | (μm) | (—) | Density | Texture | Total | Remark |
| 1 | 0.1 | 0.2 | Good | Excellent | Good | Present |
| | | | | | | Invention |
| 2 | 0.3 | 0.4 | Good | Excellent | Good | Present |
| | | | | | | Invention |
| 3 | 0.5 | 0.8 | Excellent | Excellent | Good | Present |
| | | | | | | Invention |
| 4 | 0.1 | 0.2 | Good | Excellent | Good | Present |
| | | | | | | Invention |
| 5 | 0.3 | 0.4 | Good | Excellent | Good | Present |
| | | | | | | Invention |
| 6 | 0.5 | 0.8 | Excellent | Excellent | Good | Present |
| | | | | | | Invention |
| 7 | 0.3 | 0.4 | Good | Excellent | Good | Present |
| | | | | | | Invention |
| 8 | 0.1 | 0.1 | Good | Excellent | Good | Present |
| | | | | | | Invention |
| 9 | 0.3 | 0.3 | Good | Excellent | Good | Present |
| | | | | | | Invention |
| 10 | 0.5 | 0.5 | Good | Excellent | Good | Present |
| | | | | | | Invention |
| 11 | 0.8 | 0.8 | Excellent | Excellent | Good | Present |
| | | | | | | Invention |
| 12 | 0.9 | 0.9 | Good | Excellent | Good | Present |
| | | | | | | Invention |
| 13 | 0.5 | 0.8 | Excellent | Excellent | Good | Present |
| | | | | | | Invention |
| 14 | 0.5 | 0.8 | Excellent | Excellent | Good | Present |
| | | | | | | Invention |
| 15 | 0.5 | 0.8 | Excellent | Excellent | Good | Present |
| | | | | | | Invention |
| 16 | 0.5 | 0.8 | Excellent | Excellent | Good | Present |
| | | | | | | Invention |
| 17 | 0.5 | 0.8 | Excellent | Excellent | Good | Present |
| | | | | | | Invention |
| 18 | 0.5 | 0.8 | Excellent | Excellent | Good | Present |
| | | | | | | Invention |
| 19 | 0.5 | 0.8 | Good | Excellent | Good | Present |
| | | | | | | Invention |
| 20 | 0.5 | 0.8 | Good | Excellent | Good | Present |
| | | | | | | Invention |

TABLE 3

| | | Coloring Material Layer | | | | | | |
|---|---|---|---|---|---|---|---|---|
| | | | Dispersant/ | Refractive | | Protective Layer | | |
| | | | Coloring | Index of | Average | | Refractive | |
| | | | Material | Coloring | Thickness | | Index of | |
| | Fabric | Ink | Content Ratio | Material | t1 | | Material | Forming |
| Test | Type | No | (Mass Ratio) | (—) | (μm) | Material | (—) | Method |
| 21 | Fabric 1 | 1 | 1.2 | 2.0 | 0.6 | Silicon | 1.47 | Sputtering |
| | (Polyester) | | | | | Dioxide | | |
| 22 | Fabnc 1 | 1 | 1.2 | | 0.6 | Silicon | 1.47 | Plasma CVD |
| | (Polyester) | | | | | Dioxide | | |
| 23 | Fabric 1 | 2 | 1.5 | | 0.6 | Silicon | 1.47 | Vacuum Vapor |
| | (Polyester) | | | | | Dioxide | | Deposition |
| 24 | Fabnc 1 | 3 | 2 | | 0.6 | Silicon | 1.47 | Vacuum Vapor |
| | (Polyester) | | | | | Dioxide | | Deposition |
| 25 | Fabric 1 | 4 | 3 | | 0.6 | Silicon | 1.47 | Vacuum Vapor |
| | (Polyester) | | | | | Dioxide | | Deposition |
| 26 | Fabnc 1 | 1 | 1.2 | | 0.6 | Silicon | 1.47 | Vacuum Vapor |
| | (Polyester) | | | | | Dioxide | | Deposition |
| 27 | Fabric 2 | 1 | 1.2 | | 0.6 | Silicon | 1.47 | Vacuum Vapor |
| | (Cotton) | | | | | Dioxide | | Deposition |
| 28 | Fabnc 1 | 1 | 1.2 | | 1.0 | Silicon | 1.47 | Vacuum Vapor |
| | (Polyester) | | | | | Dioxide | | Deposition |
| 29 | Fabric 1 | 1 | 1.2 | | 0.2 | Silicon | 1.47 | Vacuum Vapor |
| | (Polyester) | | | | | Dioxide | | Deposition |
| 30 | Fabric 1 | 1 | 1.2 | | 0.6 | Urethane | 1.49 | Spray |
| | (Polyester) | | | | | Resin | | Application |
| 31 | Fabric 1 | 1 | 1.2 | | 0.6 | Urethane | 1.49 | Inkjet |
| | (Polyester) | | | | | Resin | | |

| | | | | | |
|---|---|---|---|---|---|
| 32 | Fabnc 1 | 1 | 1.2 | 0.6 | Protective Layer: None |
| | (Polyester) | | | | |

| | Protective Layer | | | | | |
|---|---|---|---|---|---|---|
| | Average | | | | | |
| | Thickness | | Evaluation | | | |
| | t2 | t2/t1 | Color | | | |
| Test | (μm) | (—) | Density | Texture | Total | Remark |
| 21 | 0.5 | 0.8 | Excellent | Excellent | Good | Present |
| | | | | | | Invention |
| 22 | 0.5 | 0.8 | Excellent | Excellent | Good | Present |
| | | | | | | Invention |
| 23 | 0.5 | 0.8 | Excellent | Excellent | Good | Present |
| | | | | | | Invention |
| 24 | 0.5 | 0.8 | Excellent | Good | Good | Present |
| | | | | | | Invention |
| 25 | 0.5 | 0.8 | Excellent | Good | Good | Present |
| | | | | | | Invention |
| 26 | 1.2 | 2.0 | Poor | Good | Poor | Comparative |
| | | | | | | Example. |
| 27 | 1.2 | 2.0 | Poor | Good | Poor | Comparative |
| | | | | | | Example |
| 28 | 1.2 | 1.2 | Poor | Good | Poor | Comparative |
| | | | | | | Example |
| 29 | 0.3 | 1.3 | Poor | Good | Poor | Comparative |
| | | | | | | Example |
| 30 | 2.0 | 3.3 | Poor | Poor | Poor | Comparative |
| | | | | | | Example |
| 31 | 2.0 | 3.3 | Poor | Poor | Poor | Comparative |
| | | | | | | Example |

| | | | | | |
|---|---|---|---|---|---|
| 32 | Protective Layer: None | Poor | Excellent | Poor | Comparative |
| | | | | | Example |

Tables 2 and 3 show that irregular reflection of light on the surface of the coloring material layer was reduced and the color density was high in all of the image-formed products of Tests 1 to 25 (present invention), in which the average thickness of the protective layer was made smaller than the average thickness of the coloring material layer.

Table 3 shows that irregular reflection of light on the surface of the coloring material layer was remarkably high and the color density was low in all of the image-formed products of Tests 26 to 31 (comparative examples), in which the average thickness of the protective layer was made larger than the average thickness of the coloring material layer, and in the image-formed product of Test 32, in which the protective layer was not provided.

The present invention can provide an image forming method capable of preventing a decrease in color density in an image-formed product obtained by using an ink containing a dispersible coloring material; and the image-formed product.

Although embodiments of the present invention have been described and illustrated in detail, it is clearly understood that the same is by way of illustration and example only and not limitation, the scope of the present invention should be interpreted by terms of the appended claims

What is claimed is:

1. An image forming method, comprising:
forming a coloring material layer by applying an ink containing water and a dispersible coloring material dispersed in the water to a surface of a fabric by an inkjet method; and
forming, on a surface of the coloring material layer, a protective layer having an average thickness smaller than an average thickness of the coloring material layer.

2. The image forming method according to claim 1, wherein:
transmittance of the protective layer for light having a wavelength of 400 to 700 nm is 80% or more.

3. The image forming method according to claim 1, wherein:
when the average thickness of the coloring material layer is defined as t1 and the average thickness of the protective layer is defined as t2,
t2/t1 is 0.5 to 0.95.

4. The image forming method according to claim 1, wherein:
the protective layer contains one of an inorganic material and a resin material; and
a refractive index of the one of the inorganic material and the resin material for light having a wavelength of 589.3 nm is higher than a refractive index of air for the light and lower than a refractive index of the dispersible coloring material for the light.

5. The image forming method according to claim 4, wherein:
the refractive index of each of the inorganic material and the resin material for the light having the wavelength of 589.3 nm is 1.7 or less.

6. The image forming method according to claim 1, wherein:
the protective layer is formed by a thin film forming process.

7. The image forming method according to claim 6, wherein:
the thin film forming process is a vacuum vapor deposition method.

8. The image forming method according to claim 1, wherein:
the ink further contains at least one of a polymeric dispersant and a binder resin; and
a total content of the polymeric dispersant and the binder resin with respect to a content of the dispersible coloring material is 1.5 or less in terms of mass ratio.

9. An image-formed product, comprising:
a fabric, a coloring material layer, and a protective layer in this order, wherein
the coloring material layer contains a dispersible coloring material, and
an average thickness of the protective layer is smaller than an average thickness of the coloring material layer.

10. The image-formed product according to claim 9, wherein:
transmittance of the protective layer for light having a wavelength of 400 to 700 nm is 80% or more.

11. The image-formed product according to claim 9, wherein:
when the average thickness of the coloring material layer is defined as t1 and the average thickness of the protective layer is defined as t2,
t2/t1 is 0.5 to 0.95.

12. The image-formed product according to claim 9, wherein:
the protective layer contains one of an inorganic material and a resin material; and
a refractive index of the one of the inorganic material and the resin material for light having a wavelength of 589.3 nm is higher than a refractive index of air for the light and lower than a refractive index of the dispersible coloring material for the light.

13. The image-formed product according to claim 9, wherein:
the coloring material layer further contains at least one of a polymeric dispersant and a binder resin; and
a total content of the polymeric dispersant and the binder resin with respect to a content of the dispersible coloring material is 1.5 or less in terms of mass ratio.
